(19) United States
(12) Patent Application Publication
(10) Pub. No.: US 2019/0287979 A1
(43) Pub. Date: Sep. 19, 2019

(54) NONVOLATILE SEMICONDUCTOR MEMORY DEVICE

(71) Applicant: TOSHIBA MEMORY CORPORATION, Tokyo (JP)

(72) Inventors: Kana HIRAYAMA, Yokkaichi Mie (JP); Kazuhiko YAMAMOTO, Yokkaichi Mie (JP); Kunifumi SUZUKI, Yokkaichi Mie (JP)

(73) Assignee: TOSHIBA MEMORY CORPORATION, Tokyo (JP)

(21) Appl. No.: 16/122,541

(22) Filed: Sep. 5, 2018

(30) Foreign Application Priority Data
Mar. 14, 2018 (JP) 2018-046962

(51) Int. Cl. H01L 27/115; G11C 7/06; G11C 8/10; G11C 16/08; G11C 16/24; G11C 16/04

(52) U.S. Cl. CPC H01L 27/115; G11C 7/06; G11C 16/0483; G11C 16/08; G11C 16/24; G11C 8/10

(57) ABSTRACT

A nonvolatile semiconductor memory device includes a first wiring layer, multiple second wiring layers provided above the first wiring layer and arrayed along a direction perpendicular to a semiconductor substrate, a semiconductor layer extending along the direct ion and electrically connected to the first wiring layer, a first insulating layer extending along the direction and provided between the semiconductor layer and the multiple second wiring layers, a first oxide layer extending along the direction and provided between the first insulating layer and the multiple second wiring layers, and multiple second oxide layers having first sides being respectively in contact with the multiple second wiring layers and having second sides being in contact with the first oxide layer, a resistance value of a stacked film configured with the first oxide layer and the multiple second oxide layers varying according to a voltage being applied to the multiple second wiring layers.

### CROSS-REFERENCE TO RELATED APPLICATION

This application claims the benefit of and priority to Japanese Patent Application No. 2018-046962, filed Mar. 14, 2018, the entire contents of which are incorporated herein by reference.

### FIELD

Embodiments described herein relate generally to a nonvolatile semiconductor memory device.

### BACKGROUND

Some nonvolatile semiconductor memory devices are configured to store information with a variation in the threshold voltage of a memory cell transistor.

### DESCRIPTION OF THE DRAWINGS

FIG. 1 is a block diagram of a nonvolatile semiconductor memory device according to a first embodiment.

FIG. 2 is a perspective view of a memory cell array in the nonvolatile semiconductor memory device according to the first embodiment.

FIG. 3 is a sectional view of the memory cell array in the nonvolatile semiconductor memory device according to the first embodiment.

FIG. 4 is an equivalent circuit schematic of a memory string in the nonvolatile semiconductor memory device according to the first embodiment.

FIG. 5 is a diagram illustrating transitions of a threshold voltage in a memory cell transistor in the nonvolatile semiconductor memory device according to the first embodiment.

FIG. 6 is a sectional view illustrating a manufacturing process for the memory cell array in the nonvolatile semiconductor memory device according to the first embodiment.

FIG. 7 is a sectional view illustrating the manufacturing process for the memory cell array in the nonvolatile semiconductor memory device according to the first embodiment.

FIG. 8 is a sectional view illustrating the manufacturing process for the memory cell array in the nonvolatile semiconductor memory device according to the first embodiment.

FIG. 9 is a sectional view illustrating the manufacturing process for the memory cell array in the nonvolatile semiconductor memory device according to the first embodiment.

FIG. 10 is a sectional view illustrating the manufacturing process for the memory cell array in the nonvolatile semiconductor memory device according to the first embodiment.

FIG. 11 is a sectional view illustrating the manufacturing process for the memory cell array in the nonvolatile semiconductor memory device according to the first embodiment.

FIG. 12 is a sectional view illustrating the manufacturing process for the memory cell array in the nonvolatile semiconductor memory device according to the first embodiment.

FIG. 13 is a sectional view of a memory cell array in a nonvolatile semiconductor memory device according to a first example of a second embodiment.

FIG. 14 is a sectional view illustrating a manufacturing process for the memory cell array in the nonvolatile semiconductor memory device according to the first example of the second embodiment.

FIG. 15 is a sectional view illustrating the manufacturing process for the memory cell array in the nonvolatile semiconductor memory device according to the first example of the second embodiment.

FIG. 16 is a sectional view of a memory cell array in a nonvolatile semiconductor memory device according to a second example of the second embodiment.

### DETAILED DESCRIPTION

Embodiments provide a nonvolatile semiconductor memory device capable of preventing or reducing an increase in chip area.

According to some embodiments, a nonvolatile semiconductor memory device may include a semiconductor substrate, a first wiring layer provided above the semiconductor substrate and extending in a first direction, a plurality of second wiring layers provided above the first wiring layer, extending in a second direction intersecting with the first direction, and arrayed along a third direction intersecting with the first direction and the second direction and perpendicular to the semiconductor substrate, a semiconductor layer extending along the third direction and electrically connected to the first wiring layer, a first insulating layer extending along the third direction, being in contact with the semiconductor layer, and provided between the semiconductor layer and the plurality of second wiring layers, a first oxide layer extending along the third direction, being in contact with the first insulating layer, and provided between the first insulating layer and the plurality of second wiring layers, and a plurality of second oxide layers having first sides being respectively in contact with the plurality of second wiring layers and having second sides being in contact with the first oxide layer, a resistance value of a stacked film configured with the first oxide layer and the plurality of second oxide layers varying according to a voltage being applied to the plurality of second wiring layers.

Hereinafter, embodiments will be described with reference to the drawings. Furthermore, in the following description, constituent elements having approximately the same functions or configurations are assigned the respective same reference characters, and a repeated description thereof is performed only on an as-needed basis. Moreover, each embodiment described below is taken as an example for illustrating a device or method which embodiments a technical idea of the embodiment, and the technical idea of each embodiment should not be construed to specify, for example, the material, shape, structure, and location of each constituent component to those described below. The technical idea of each embodiment can be changed or modified in various manners within the scope of claims.

### 1. First Embodiment

A nonvolatile semiconductor memory device according to a first embodiment is described.

### 1.1 Configuration

1.1.1 Overall Configuration of Nonvolatile Semiconductor Memory Device

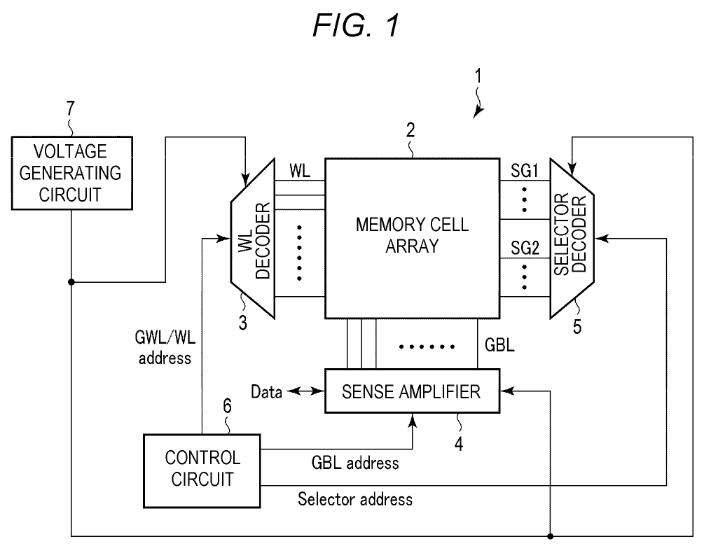

First, an overall configuration of the nonvolatile semiconductor memory device according to the first embodiment is described with reference to FIG. 1. FIG. 1 is an example of a block diagram illustrating a basic overall configuration of the nonvolatile semiconductor memory device. Furthermore, while, in FIG. 1, some connections between blocks are indicated by arrow lines, the connections between blocks are not limited to these.

As illustrated in FIG. 1, the nonvolatile semiconductor memory device 1 includes a memory cell array 2, a WL decoder 3, a sense amplifier 4, a selector decoder 5, a control circuit 6, and a voltage generating circuit 7.

The memory cell array 2 may include a plurality of memory cell transistors arranged in a matrix configuration. Each memory cell transistor may be configured to store data in a nonvolatile manner. Furthermore, details of the memory cell transistor are described below.

The WL decoder 3 includes a word line selection unit (or a word line selector) and a word line driver, which are not illustrated. The word line selection unit may select a word line WL based on a WL address received from the control circuit 6. The word line driver may apply, to a selected word line WL and a non-selected word line WL, voltages needed for, for example, a readout operation and a write operation for data.

The sense amplifier 4 may select a global bit line GBL based on a GBL address received from the control circuit 6, and apply, to the selected global bit line GBL, a voltage needed for, for example, a readout operation and a write operation for data. During the readout operation for data, the sense amplifier 4 may sense data read out from a memory cell transistor. Moreover, during the write operation for data, the sense amplifier 4 may transfer write data to a memory cell transistor.

The selector decoder 5 may include a selector selection unit (or select gate line selector) and a selector driver, which are not illustrated. The selector selection unit may select gate lines SG1 and SG2 based on selector addresses received from the control circuit 6. The selector driver may apply voltages needed for, for example, a readout operation and a write operation for data to selected select gate lines SG1 and SG2 and non-selected select gate lines SG1 and SG2.

The control circuit 6 may control an operation of the entire nonvolatile semiconductor memory device 1. More specifically, the control circuit 6 may control the WL decoder 3, the sense amplifier 4, the selector decoder 5, and the voltage generating circuit 7 in, for example, a readout operation and a write operation for data. Moreover, the control circuit 6 may send a WL address to the WL decoder 3, send a GBL address to the sense amplifier 4, and send a selector address to the selector decoder 5.

The voltage generating circuit 7 may generate voltages needed according to control performed by the control circuit 6, and supply the voltages to, for example, the WL decoder 3, the sense amplifier 4, and the selector decoder 5.

1.1.2 Configuration of Memory Cell Array

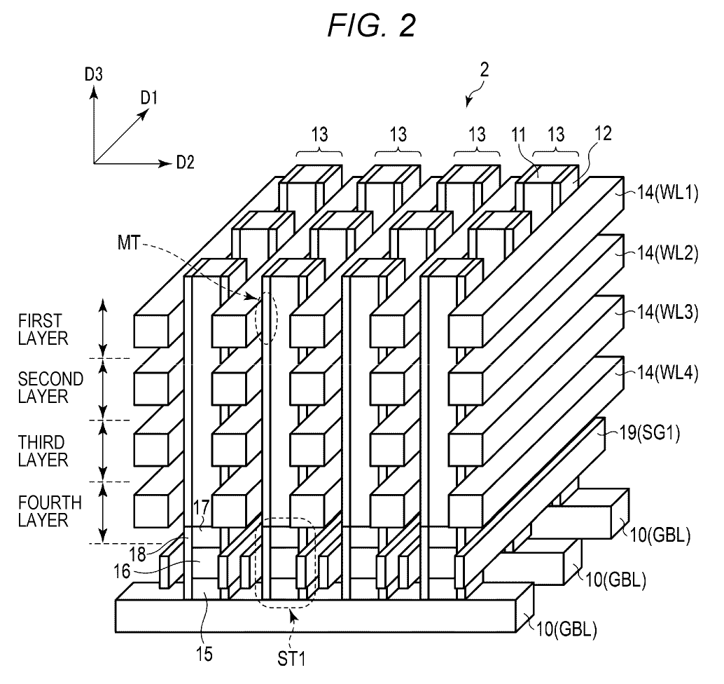

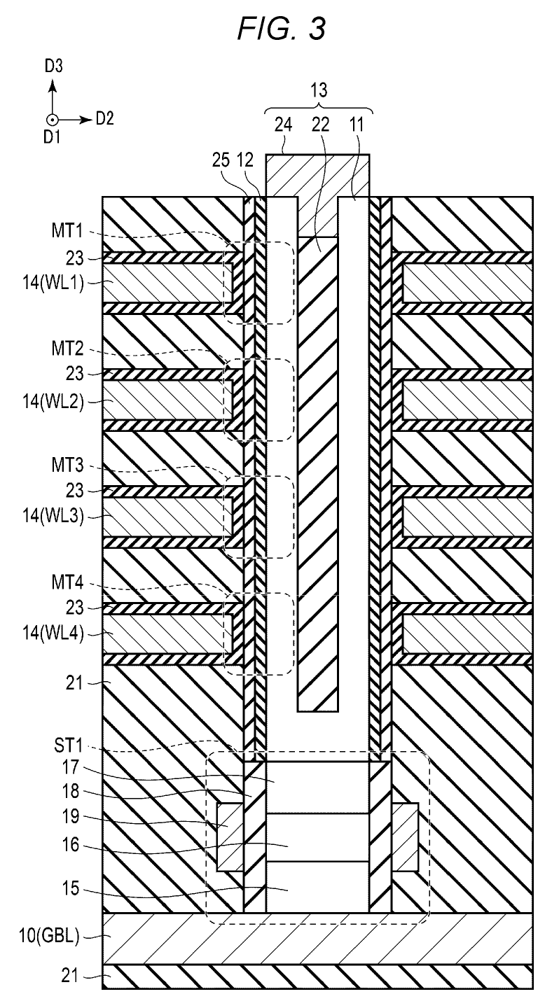

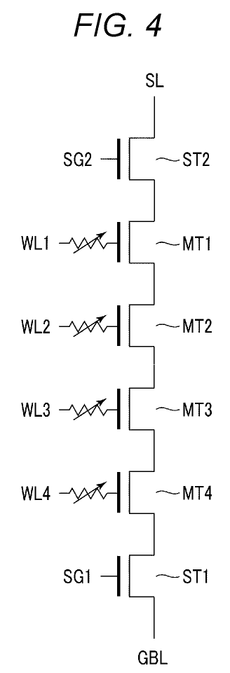

Next, a configuration of the memory cell array 2 according to the first embodiment is described with reference to FIG. 2 to FIG. 4. FIG. 2 is a perspective view of the memory cell array 2. FIG. 3 is a sectional view of the memory cell array 2. FIG. 4 illustrates an example of an equivalent circuit of a memory string. Furthermore, in an example illustrated in FIG. 2, interlayer insulating films are omitted from illustration.

As illustrated in FIG. 2, the memory cell array 2 may contain GBL wiring layers 10, select transistors ST1, memory strings 13, and WL wiring layers 14. The GBL wiring layers 10 may serve as global bit lines GBL. The WL wiring layers 14 may serve as word lines WL1 to WL4. Furthermore, the numbers of global bit lines GBL, word lines WL, and memory strings 13 can be set to arbitrary numbers.

The GBL wiring layers 10 may be located, for example, at the lowermost layer of the memory cell array 2. The GBL wiring layers 10, each of which extends along a second direction D2 parallel to the semiconductor substrate, may be arrayed along a first direction D1 parallel to the semiconductor substrate and perpendicular to the second direction D2. Each GBL wiring layer 10 may be configured with an electrical conducting material, which includes, for example, tungsten (W) as a metal material.

The select transistors ST1 may be provided on the GBL wiring layers 10. Each select transistor ST1 may be, for example, a thin-film transistor (TFT). Hereinafter, a case in which the select transistor ST1 is a TFT is described. The select transistor ST1 includes a source region 15, a channel region 16, a drain region 17, a gate insulating layer 18, and an SG1 wiring layer 19 serving as a select gate line SG1 (see FIG. 3).

Along a third direction D3 intersecting with the first direction D1 and the second direction D2 and perpendicular to the semiconductor substrate, the Source region 15, the channel region 16, and the drain region 17 may be sequentially formed on the GBL wiring layer 10. The memory string 13 may be formed on the drain region 17. The source region 15 and the drain region 17 may be made from, for example, polycrystalline silicon doped with, for example, Phosphorus (P). The channel region 16 may be made from, for example, polycrystalline silicon. The gate insulating layer 18 may be formed on the side surfaces of the source region 15, the channel region 16, and the drain, region 17. The gate insulating layer 18 may be made from, for example, silicon dioxide film (SiO₂).

Referring to FIG. 2 and FIG. 3, the SG1 wiring layer 19 may be in contact with the gate insulating layer 18 in the second direction D2 and extends along the first direction D1. The SG1 wiring layer 19 may be connected to gate insulating layers 18 of a plurality of select transistors ST1 arranged along the first direction D1 in common. The SG1 wiring layer 19 may be configured with an electrical conducting material and can be made from, for example, a metal material such as W. As viewed from the second direction D2, the SG1 wiring layer 19 may overlap an upper portion of the source region 15, the entirety of the channel region 16, and a lower portion of the drain region 17. In the first embodiment, each select transistor ST1 may include two SG1 wiring layers 19. Thus, each select transistor ST1 may include two gate insulating layers 18 respectively connected to different SG1 wiring layers 19 with respect to a set of the source region 15, the channel region 16, and the drain region 17. In other words, two TFTs may be provided per memory string 13, sharing the source region 15, the channel region 16, and the drain region 17. The gates thereof may be respectively connected to different: select gate lines SG1. Furthermore, in the example illustrated in FIG. 2, the SG1 wiring layer 19 may be provided at both sides of the select transistor ST1, but can be provided at only one side thereof.

The WL wiring layers 14 may be formed at positions higher than the GBL wiring layers 10 and the select transistors ST1 in the third direction D3, which is perpendicular to the semiconductor substrate. The WL wiring layers 14, each of which extends along the first direction D1, may be arrayed along the second direction D2. Moreover, the WL wiring layers 14 may be provided as a plurality of layers (the first layer, the second layer, . . . ) arranged along the third direction D3, and an interlayer insulating film (not illustrated) may lie (or be disposed) between every adjacent WL wiring layers 14. In the example illustrated in FIG. 2, four WL wiring layers 14 (the first layer to the fourth layer) are provided, and respectively serve as word lines WL1 to WL4. Hereinafter, in the case of distinguishing between the WL wiring layers 14 at the first layer to the fourth layer, the WL wiring layer 14 at the uppermost layer (the first layer) serving as a word line WL1 is referred to as a “first WL wiring layer 14”. The WL wiring layer 14 at the second layer serving as a word line WL2 is referred to as a “second WL wiring layer 14”. The WL wiring layer 14 at the third layer serving as a word line WL3 is referred to as a “third WL wiring layer 14”. The WL wiring layer 14 at the lowermost layer (the fourth layer) serving as a word line WL4 is referred to as a “fourth WL wiring layer 14”. Furthermore, the number of layers of the WL wiring layers 14 can be set to an arbitrary number.

The WL wiring layer 14 may be configured with an electrically conducting material, and can be made from, for example, a metal material such as titanium nitride (TiN) or w. In a case where the WL wiring layer 14 is made from W, for example, TiN can be formed as a barrier metal for W at an interface between an insulating film 21 and W. In the first embodiment, a case in which the WL wiring layer 14 is made from TiN is described.

As illustrated in FIG. 2, the memory string 13 may include a semiconductor layer 11 and an insulating layer 12. The memory string 13 may extend along the third direction D3 between WL wiring layers 14 adjacent along the second direction D2, and a plurality of memory strings 13 may be arranged along the first direction D1 and the second direction D2. One end (e.g., bottom surface) of the memory string 13 may be connected to the drain region 17, which is an upper end of the select transistor ST1. In a two-dimensional plane formed by the first direction D1 and the second direction D2, memory strings 13 arrayed in the same row along the second direction D2 may be electrically connected to the same GBL wiring layer 10.

A region surrounded by one word line WL and one memory string 13 may serve as one memory cell transistor MT. The semiconductor layer 11 may be a region in which a channel of the memory cell transistor MI is formed. The semiconductor layer 11 may be made from at least one of silicon (Si), germanium (Ge), or a compound of those. Hereinafter, in the first embodiment, a case in which the semiconductor layer 11 is made from polycrystal silicon is described.

The insulating layer 12 may be formed on at least a part of the side surfaces of the memory string 13. The insulating layer 12 may be provided to prevent a leak current from flowing between the word line WL and the semiconductor layer 11, for example, when a voltage is applied to the word line WL. The insulating layer 12 in the first embodiment may be provided at the side surface of the memory string 13 adjacent to the WL wiring layer 14 in the second direction D2. Furthermore, the insulating layer 12 can be provided in such a way as to surround the side surfaces of the semiconductor layer 11.

The insulating layer 12 may be made, for example, from aluminum oxide (AlOₓ). Furthermore, the insulating layer 12 is not limited to AlOₓ, but can be made from hafnium oxide (HfOₓ), zirconium oxide (ZrOₓ), tantalum oxide (TaOₓ), SiO₂, germanium oxide (GeOₓ), or a high-resistance oxide using a stacked film of these materials.

Next, a cross-section structure of the memory cell array 2 is described.

As illustrated in FIG. 3, the GBL wiring layer 10 extending in the second direction D2 is formed on the insulating layer 21, and the select transistor ST1 is formed on the GBL wiring layer 10. Then, the memory string 13 extending in the third direction D3 is formed in such a manner that the bottom surface thereof is connected to the select transistor ST1. The memory string 13 may include an oxide layer 25, the insulating layer 12, the semiconductor layer 11, and an insulating layer 22. The oxide layer 25 and the insulating layer 12 are stacked at the side surfaces of the memory string 13. One side surface of the semiconductor layer 11 is in contact with the insulating layer 12, and the other side surface thereof is in contact with the insulating layer 22. The insulating layer 22 is provided between portions of the semiconductor layer 11. Moreover, an electrode 24 is provided at an upper portion of the memory string 13. The electrode 24 is able to be used to interconnect, for example, the semiconductor layer 11 and a wiring layer (source line) not illustrated).

The oxide layer 25 is a resistance-variable film containing oxygen defects (holes). The oxide layer 25 is made from, for example, a low-resistance high-dielectric metal oxide, such as crystallized titanium oxide (TiOₓ), tungsten oxide (WOₓ), niobium oxide (NbOₓ), or molybdenum oxide (MoOₓ). Hereinafter, in the present embodiment, a case in which the oxide layer 25 is made from TiOₓ is described.

The insulating layer 22 may be made from, for example, SiO₂. The electrode 24 may be configured with an electrical conducting material, and can be made from, for example, polycrystalline silicon doped with P or can be made from a metal material such as W.

The film thickness of the oxide layer 25 in the second direction D2 may be desirably equal to or greater than 1 nanometer (nm) and equal to or less than 5 nm. If the film thickness of the oxide layer 23 is less than 1 nm, it becomes difficult to form the oxide layer 25 as a film. Moreover, if the film thickness of the oxide layer 25 is greater than 5 nm, the oxide layer 25 is crystallised and is reduced in resistance value, so that a leak current flowing between the respective WL wiring layers 14 increases.

The film thickness of the insulating layer 12 in the second direction D2 may be desirably equal to or greater than 5 nm and equal to or less than 10 nm. If the film thickness of the insulating layer 12 is less than 5 nm, a leak current increases, so that, when a current is caused to flow through the memory string 13, the load on a driver for the GBL wiring layer 10 increases. Thus, it becomes impossible to cause a current needed for cell driving to flow through the GBL wiring layer 10. Moreover, if the film thickness of the insulating layer 12 is greater than 10 nm, an interval between the word line WL and the memory string 13 becomes wide, so that, since the size of the memory cell transistor MT becomes large, the chip area increases. Additionally, in the case of boring a hole used for forming the memory string 13 in the insulating layer 21 and forming the oxide layer 25 and the insulating layer 12 on the side surface of the hole, if the film thickness of the insulating layer 12 is greater than 10 nm, the possibility of occurrence of a deficiency in embedding in the hole increases.

The film thickness and material of each of, for example, the insulating layer 12 and the oxide layer 25 can be examined by, for example, energy dispersive X-ray spectroscopy (EDX) mapping of field emission transmission electron microscopy (FE-TEM).

The WL wiring layers 14 may be stacked in layers in the third direction D3 with the insulating layer 21 lying therebetween. More specifically, the word lines WL4 to WL1 may be stacked in layers in order from the lower layer. The upper surface, bottom surface, and a part of side surfaces of the WL wiring layer 14 may be covered with an oxide layer 23. The one side surface of the WL wiring layer 14 may be in contact with the oxide layer 25 of the memory string 13 via the oxide layer 23. A region surrounded by the first WL wiring layer 14, which serves as the word line WL1, and the memory string 13 may serve as a memory cell transistor MT1. With regard to the word lines WL2, WL3, and WL4, similarly, regions surrounded by the respective corresponding second to fourth WL wiring layers 14 and the memory string 13 may serve as memory cell transistors MT2, MT3, and MT4, respectively.

The oxide layer 23 may be a resistance-variable film containing oxygen defects (e.g., holes), as with the oxide layer 25. Oxygen defects of the oxide layers 23 and 25 may transfer inside the oxide layers 23 and 25 according to an electric field between the word line WL and the semiconductor layer 11. In other words, the oxygen concentration distribution in a stacked film (or stacked region) configured with the oxide layer 23 and the oxide layer 25 may be controlled by the electric field. Accordingly, the stacked film configured with the oxide layer 23 and the oxide layer 25 may serve as a resistance-variable film of the memory cell transistor MT.

The oxide layer 23 may be made from, for example, a low-resistance high-dielectric metal oxide, such as titanium oxide (TiOₓ), tungsten oxide (WOₓ), niobium oxide (NbOₓ), or molybdenum oxide (MoOₓ) The oxide layer 23 and the oxide layer 25 can be made from the same material or can be made from different materials. The stacked film configured with the oxide layer 23 and the oxide layer 25 may be in a crystallized state. For example, even when the oxide layer 23 and the oxide layer 25 are made from the same material, as a result of crystallization, grains (or crystal grains) of the oxide layer 23 and grains of the oxide layer 25 may be divided from each other at an interface between the oxide layer 23 and the oxide layer 25, and a dividing surface thereof can be observed with, for example, FE-TEM. Hereinafter, in the first embodiment, a case in which the oxide layer 23 is made from TiOₓ as with the oxide layer 25 is described.

It is desirable that the film thickness of the oxide layer 23 in the second direction D2 be equal to or greater than 5 nm and equal to or less than 20 nm in combination with the film thickness of the oxide layer 25. If the film thickness of the stacked film configured with the oxide layers 23 and 25 is less than 5 nm, the stacked film becomes unable to be crystallized. Moreover, if the film thickness of the stacked film is greater than 20 nm, a distance between the word line WL and the memory string 13 becomes wide, so that, since the size of the memory cell transistor MT in the lateral direction (or second direction D2) becomes large, the chip area increases. Moreover, if the oxide layer 23 becomes thick, the distance between word line WL wirings in the longitudinal direction (third direction D3) becomes long, so that processing and embedding of the memory strings 13 become difficult. For example, a configuration in which the film thickness of the oxide layer 23 is set to be equal to or less than 5 nm and, while a stacked film configured with the oxide layers 23 and 25 is crystallized by thermal treatment, regions in which each of the oxide layers 23 and 25 is present as a single layer are not crystallized can be employed.

Next, an equivalent circuit corresponding to the memory cell transistors MT1 to MT4 is described. In the following description, in a case where the source and drain of a transistor are not specified, any one of the source and drain of the transistor is referred to as “one end of the transistor”, and the other of the source and drain of the transistor is referred to as “the other end of the transistor”.

As illustrated in FIG. 4, the memory cell transistors MT1 to MT4 may be interconnected in series with respect to their current pathway. Then, the gates of the memory cell transistors MT1 to MT4 may be connected to the word lines WL1 to WL4, respectively, via variable resistance elements each corresponding to the stacked film configured with the oxide layers 23 and 25. One end of the memory cell transistor MT1 may be connected to one end of a select transistor ST2. The other end of the select transistor ST2 may be connected to a source line SL and a gate the reef may be connected to the select gate line SG2. The select transistor ST2 may be a transistor which connects the memory string 13 and the source line SL. Furthermore, the select transistor ST2 can be provided inside the memory string 13, can be provided above the memory string 13 along the third direction D3, or can be provided in a region other than the memory cell array 2. A voltage may be applied to the select gate line SG2 from the selector decoder 5. Moreover, a voltage may be applied to the source line SL from the voltage generating circuit 7 via, for example, a source line driver (not illustrated). One end of the memory cell transistor MT4 may be connected to the select transistors ST1. The other end of the select transistors ST1 may be connected to the global bit line GBL and a gate thereof may be connected to the select gate line SG1.

### 1.2 Write Operation and Erasing Operation of Memory Cell Transistor

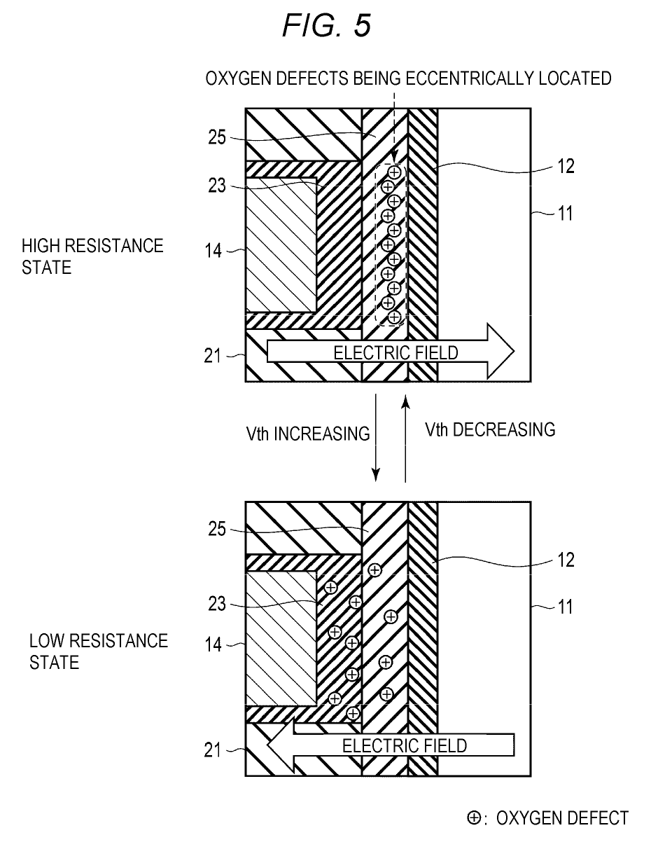

Next, a write operation and an erasing operation of the memory cell transistor MT are briefly described. FIG. 5 is a diagram used to describe a write operation and an erasing operation of the memory cell transistor MT.

As illustrated in FIG. 5, for example, when, as an erasing operation, an electric field is applied from the WL wiring layer 14 toward the semiconductor layer 11, in other words, from the word line WL toward a channel of the memory cell transistor MT, oxygen defects in the stacked film configured with the oxide layers 23 and 25 may become eccentrically located in the vicinity of an interface between the oxide layer 25 and the insulating layer 12. With this, the resistance value of the stacked film becomes high, and the band alignment of an interface between the stacked film and the semiconductor layer 11 changes. As a result, the channel resistance in the semiconductor layer 11 changes, and a threshold voltage Vth of the memory cell transistor MT required for channel inversion becomes low. On the other hand, when, as a write operation, an electric field is applied from the semiconductor layer 11 toward the WL wiring layer 14, in other words, from the channel toward the word line WL, oxygen defects in the stacked film become not eccentrically located in the vicinity of an interface between the oxide layer 25 and the insulating layer 12. With this, the resistance value of the stacked film becomes low, and the threshold voltage Vth of the memory cell transistor MT becomes high. In this way, changing the direction of an electric field applied to the memory cell transistor MT between the write operation and the erasing operation causes the distribution of oxygen concentrations of the stacked film configured with the oxide layers 23 and 25 to change and causes the threshold voltage Vth to vary. As a result, the memory cell transistor MT is enabled to store data associated with the threshold voltage Vth in a nonvolatile manner. The memory cell transistor MT is able to store data with two bits (or quaternary value) or more according to threshold levels.

### 1.3 Method for Manufacturing Memory Cell Array

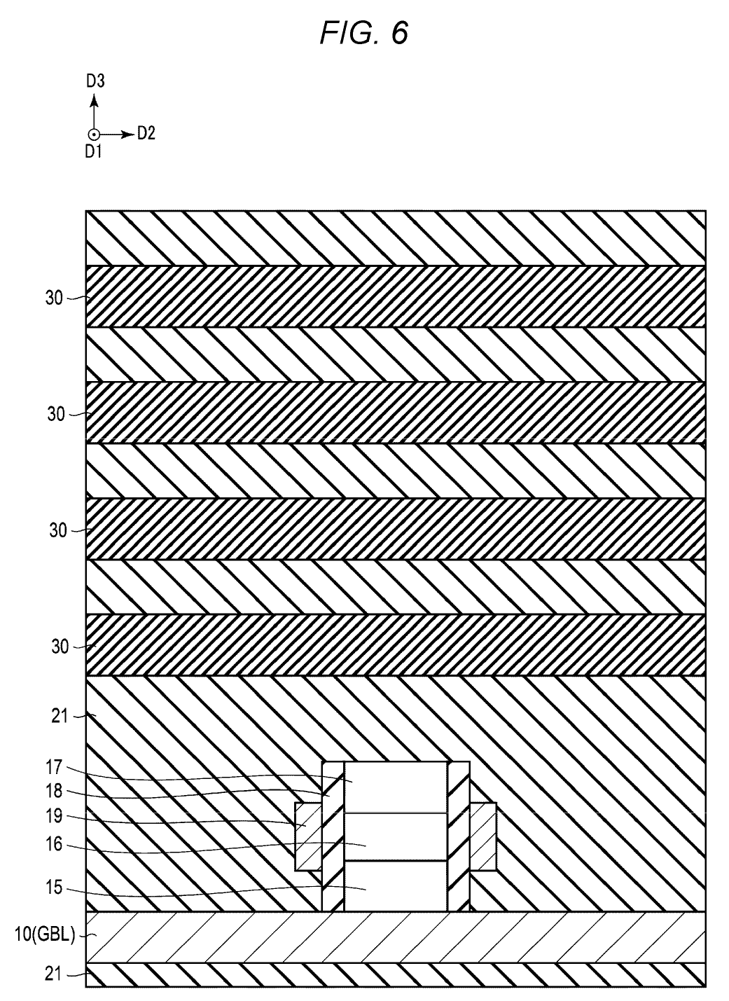

Next, a method for manufacturing a memory cell array is described with reference to FIG. 6 to FIG. 12. FIG. 6 to FIG. 12 illustrate sectional views of the memory cell array 2 in respective manufacturing processes of the memory cell array 2. In the first embodiment, a method of, after forming a structure corresponding to the WL wiring layer 14 and the oxide layer 23 with a sacrificial layer 30, removing the sacrificial layer 30 and then performing embedding with the WL wiring layer 14 and the oxide layer 23 (hereinafter referred to as a “back-filling method”) is described. In the following description, a case in which a silicon nitride (SiN) film is used as the sacrificial layer 30 is described. Furthermore, the sacrificial layer 30 is not limited to SiN. For example, the sacrificial layer 30 can be a silicon ox nitride film (SiON), or any material capable of sufficiently attaining the selectivity of wet etching with respect to the insulating layer 21 (for example, SiO₂).

Furthermore, in the following description, the method of forming the GBL wiring layer 10 and the select transistor ST1 (e.g., the source region 15, the channel region 16, the drain region 17, the gate insulating, layer 18, and the SG1 wiring layer 19) is omitted from description, and method of forming the memory string 13 and the WL wiring layer 14 is described. Moreover, in an example illustrated in FIG. 6 to FIG. 12, for ease of description, only one memory string 13 and WL wiring layer 14 located at both sides of the memory string 13 are illustrated, and a case in which slits SLT are formed at side surfaces of the WI wiring layers 14 along the second direction D2 is illustrated.

As illustrated in FIG. 6, first, after forming the GBL wiring layer 10 and the select transistor ST1 on the insulating layer 21, the method may form the insulating layer 21 again and embeds the GBL wiring layer 10 and the select transistor ST1, Next, the method may stack four sacrificial layers 30 in layers with the insulating layer 21 lying (or interposed) between adjacent sacrificial layers 30, and re-form the insulating layer 21 on the uppermost sacrificial layer 30.

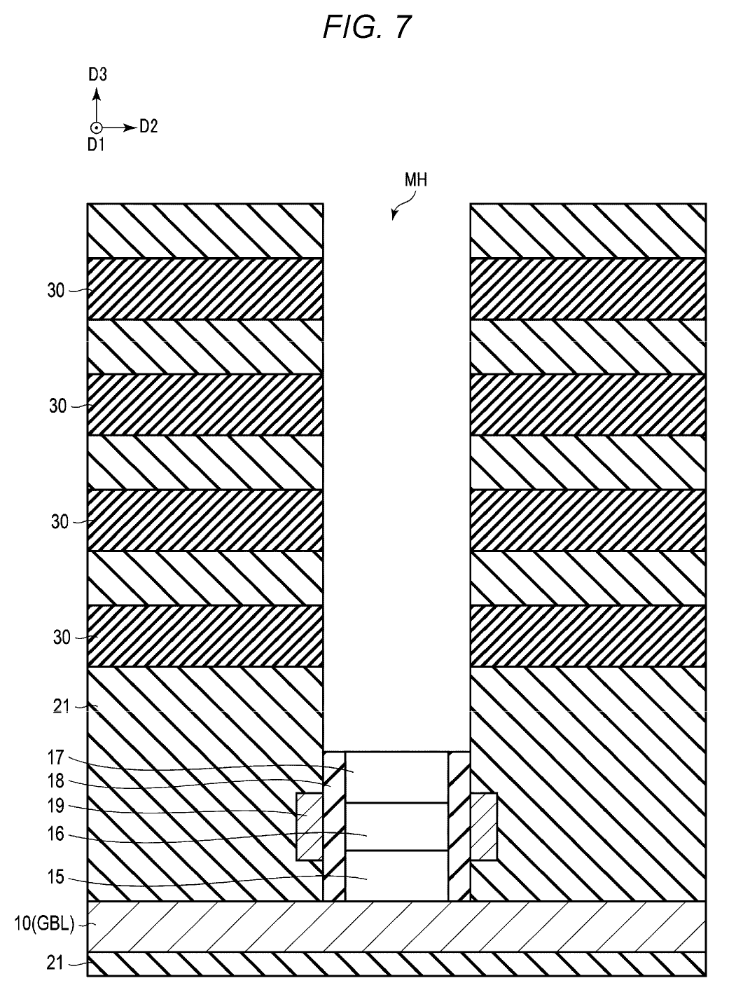

As illustrated in FIG. 7, next, to form the memory string 13, the method may form a memory hole MH such that the bottom surface of the memory hole MH reaches the drain region 17 of the select transistor ST1.

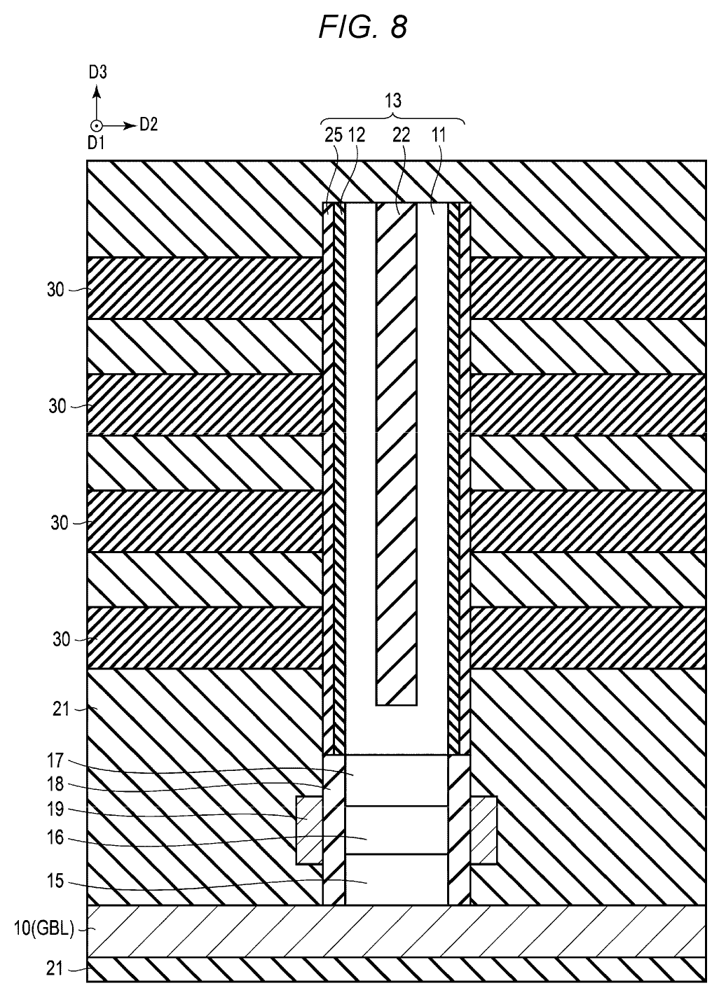

As illustrated in FIG. 8, next, after forming the memory string 13 by embedding the oxide layer 25, the insulating layer 12, the semiconductor layer 11, and the insulating layer 22 into the memory hole MH, the method may form the insulating layer 21 in such a way as to cover the memory string 13. More specifically, after boring the memory hole MH, first, the method may stack the oxide layer 25 and the insulating layer 12 in layers on the memory hole MH. For example, in a case where the oxide layer 25 is made from TiOₓ, the method can form TiOₓ by forming a thin film containing Ti via chemical vapor deposition (CVD) or atomic layer deposition (ALD) using, for example, an organic Ti source or titanium tetrachloride (TiCl₄) and then performing plasma oxidation on the thin film. Next, the method may remove the oxide layer 25 and the insulating layer 12 on the bottom portion of the memory hole MH and the insulating layer 21 by anisotropic etching. Next, after performing embedding in the memory hole MH by stacking the semiconductor layer 11 and the insulating layer 22 in layers, the method may remove the semiconductor layer 11 and the insulating layer 22 on the insulating layer 21, thus forming the memory string 13. Next, the method may form the insulating layer 21 to perform embedding of the memory string 13.

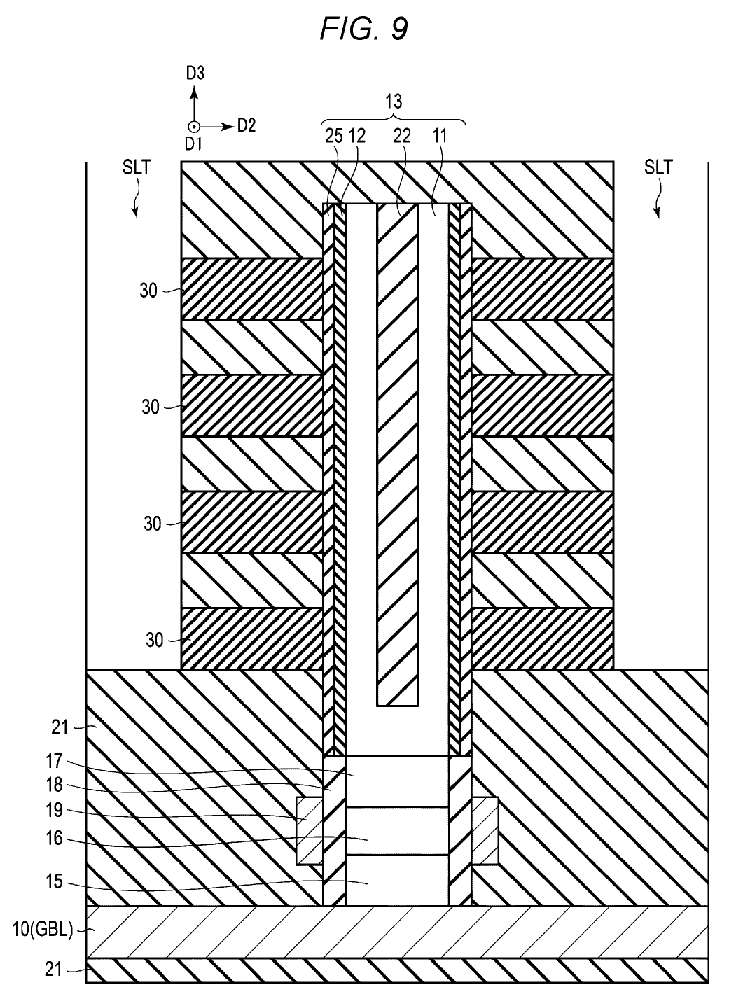

As illustrated in FIG. 9, next, the method may form slits SLT extending in the first direction D1 in such a manner that four sacrificial layers 30 become exposed on the side surfaces thereof. Furthermore, in a configuration of the memory cell array 2 illustrated in FIG. 2, the memory strings 13 and the WL wiring layers 14 may be alternately formed one by one along the second direction D2, so that there are no locations at which to form slits SLT in the second direction D2. In such a case, a slit SLT can be formed between two memory strings 13 arranged along the first direction D1.

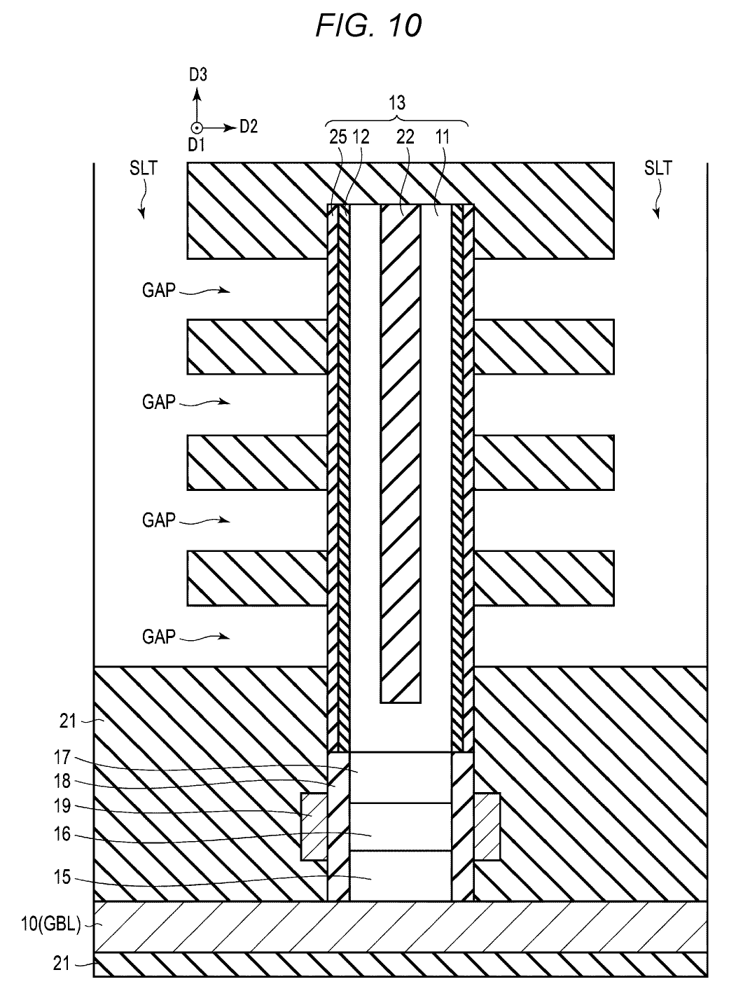

As illustrated in FIG. 10, next, in a case where the sacrificial layer 30 is SiN, the method may perform wet etching using phosphoric acid (H₃PO₄). With this, the sacrificial layer 30 may be etched from the side of the slit SLT, so that a gap is formed at a portion previously occupied by the sacrificial layer 30.

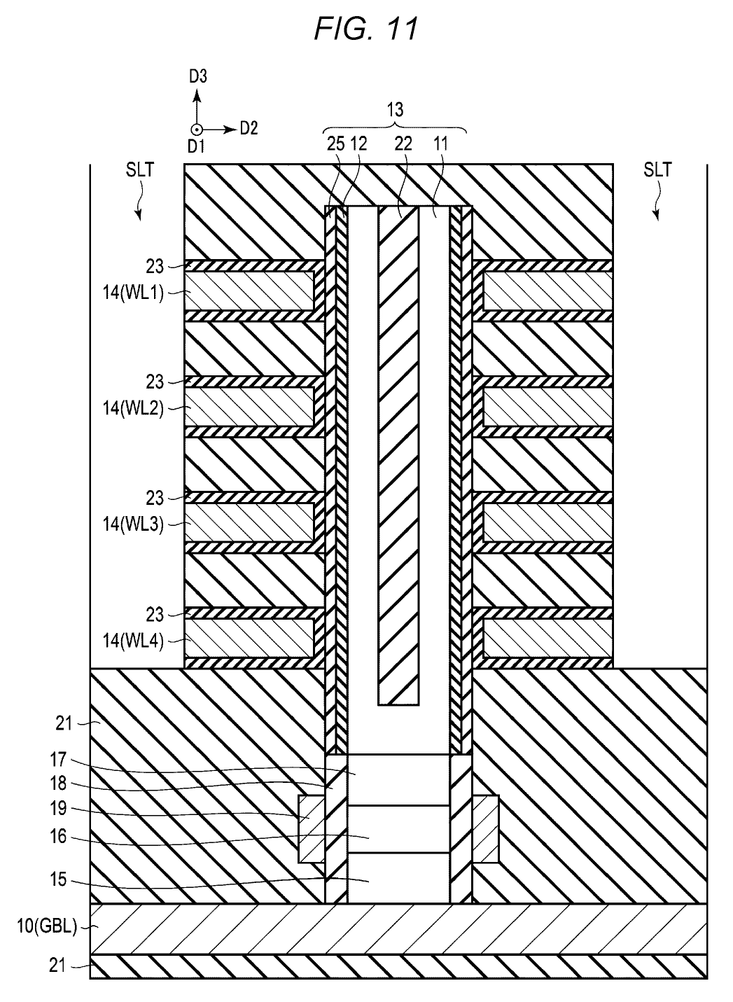

As illustrated in FIG. 11, next, the method may form the oxide layer 23 and the WL wiring layer 14. More specifically, first, the method may form, for example, TiOₓ as the oxide layer 23 as with the oxide layer 25. Next, the method may perform thermal treatment at, for example, 400° C. to 1000° C. With this, TiOₓ may be crystallized in at least a stacked region configured with the oxide layers 23 and 25. For example, performing thermal treatment at 400° C. or more may cause TiOₓ to have an anatase structure and enable the oxygen concentration (or hole concentration) in a film to be controlled by an electric field. Next, as, for example, the WL wiring layer 14, the method may form TiN with such a film thickness as not to perform complete embedding of the slit SLT. After that, the method may remove TiOₓ and TiN formed on the side surface and bottom portion of the slit SLT and on the insulating layer 21. With this, the WL wiring layer 14 and the oxide layer 23 may be formed.

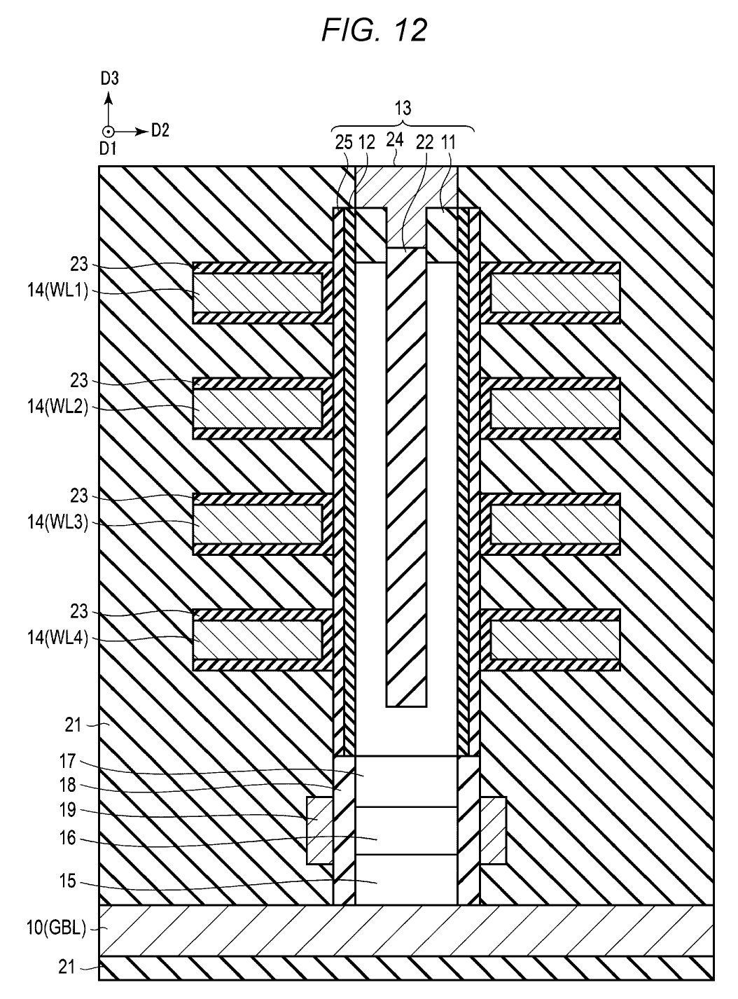

As illustrated in FIG. 12, next, after embedding SiO₂ in the slit SLT, the method may form the electrode 24.

### 1.4 Advantageous Effect According to First Embodiment

With a configuration according to the first embodiment employed, an increase in chip area can be prevented or reduced. Such an advantageous effect is described in detail.

For example, in a case where an oxide layer with a film thickness of 8 nm is formed as a resistance-variable film (e.g., oxygen defect film) of the memory cell transistor MT, if the oxide layer 23 is formed with a film thickness of 8 nm while the oxide layer 25 is omitted, the film thickness of the oxide layer 23 which is in contact with the upper surface and bottom surface of the WL wiring layer 14 becomes large, so that the wiring interval between the WL wiring layers 14 becomes wide and the size of the memory cell transistor MT in the longitudinal direction (or third direction D3) becomes large. If the height of the memory string 13 becomes large in this way, boring failure in boring the memory hole MH or embedding failure becomes apt to occur. Moreover, if the oxide layer 25 is formed with a film thickness of 8 nm while the oxide layer 23 is omitted, the oxide layer 25 may be crystallized in such a way as to have a low resistance value, thus causing a leak between the stacked word lines WL.

On the other hand, with a configuration according to the first embodiment employed, a resistance-variable film (e.g., oxygen defect film) of the memory cell transistor can be formed of a stacked film configured with the oxide layers 23 and 25. With this, the film thickness of each of the oxide layers 23 and 25 can be made smaller than the film thickness required as a resistance-variable film. Reducing the film thickness of the oxide layer 23 enables decreasing the size of the memory cell transistor MT in the longitudinal direction. Accordingly, the height of the memory string 13 can be decreased, a three-dimensional stacked-type memory can be easily integrated at high density, and an increase of the chip area of a nonvolatile semiconductor memory device can be prevented or reduced.

Furthermore, since the height of the memory string 13 can be decreased, the occurrence of boring failure of the memory hole MH or embedding failure can be reduced. Accordingly, the reliability of a nonvolatile semiconductor memory device can be improved.

Moreover, since the film thickness of the oxide layer 25 can be made small, crystallization of the oxide layer 25 present as a single layer between the WL wiring layers 14 can foe prevented or reduced. With this, a decrease in resistance value of the oxide layer 25 can be prevented or reduced, and a leak current flowing between the stacked word lines WL can be prevented or reduced. Therefore, the reliability of a nonvolatile semiconductor memory device can be improved.

Furthermore, since the oxide layers 23 and 25 present between the WL wiring layer 14 and the semiconductor layer 11 are not exposed to an atmosphere of dry etching, there is no deterioration of film quality caused by etching damage, and variations in characteristic of the memory cell transistor MT can be reduced.

Moreover, since a dividing surface of crystallized grains is formed at an interface between the oxide layer 23 and the oxide layer 25, the threading dislocation which penetrates through the oxide layer 23 and the oxide layer 25 is unlikely to occur, so that a decrease in reliability of the memory cell transistor MT caused by, for example, defects can be prevented or reduced.

Furthermore, since the film thickness of each of the oxide layers 23 and 25 can be made small, a process time in a film formation process and an etching process is enabled to be reduced, so that the processing capacities of a film formation apparatus and an etching apparatus can be improved and process costs can be reduced.

### 2. Second Embodiment

Next, a second embodiment is described. In the second embodiment, two examples are described about a structure of the memory cell array 2 different from that in the first embodiment. In the following description, only differences from those of the first embodiment are described.

### 2.1 First Example

A structure of the memory cell array 2 according to a first example is described.

2.1.1 Cross-Section Structure of Memory Cell Array

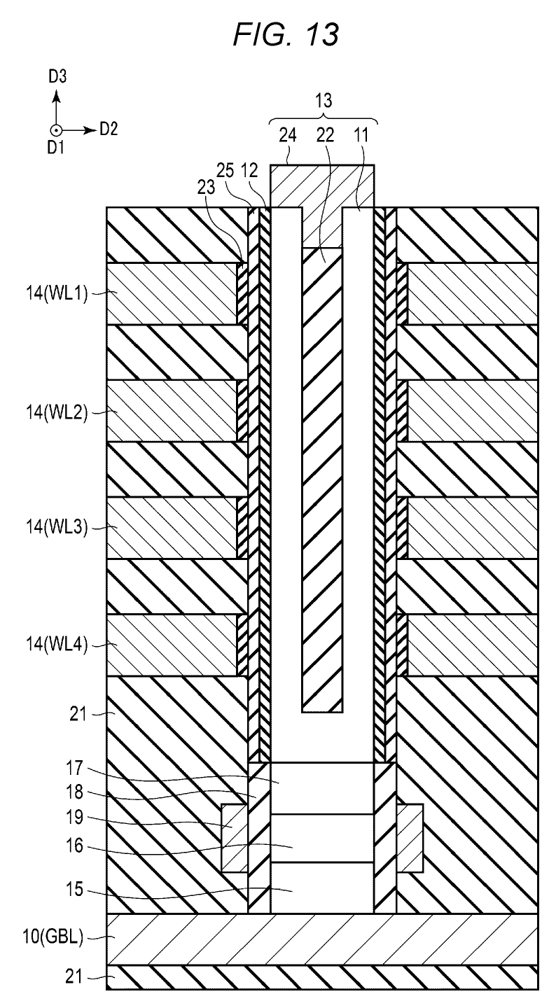

First, a cross-section structure of the memory cell array 2 is described with reference to FIG. 13.

As illustrated in FIG. 13, the oxide layer 23 may be formed on one side surface of the WL wiring layer 14, i.e., between the WL wiring layer 14 and the oxide layer 25, and may not be formed on the upper surface and bottom surface of the WL wiring layer 14. Hereinafter, such a structure of the oxide layer 23 is referred to as a “Levelling-off structure”. The other configurations are similar to those illustrated in FIG. 3 of the first embodiment.

In the second embodiment, a metal material used to make the WL wiring layers 14 may be the same as a metal material of the oxide layer 23. For example, in a case where the WL wiring layer 14 is made from W, WOₓ may be formed as the oxide layer 23. Moreover, in a case where the WL wiring layer 14 is made from TiN, TiOₓ may be formed as the oxide layer 23.

2.1.2 Method for Manufacturing Memory Cell Array

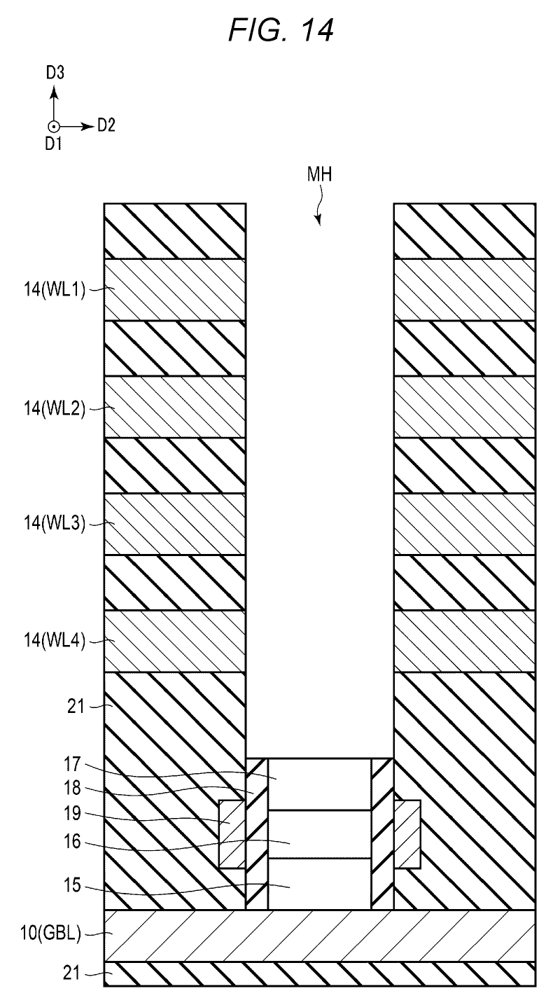

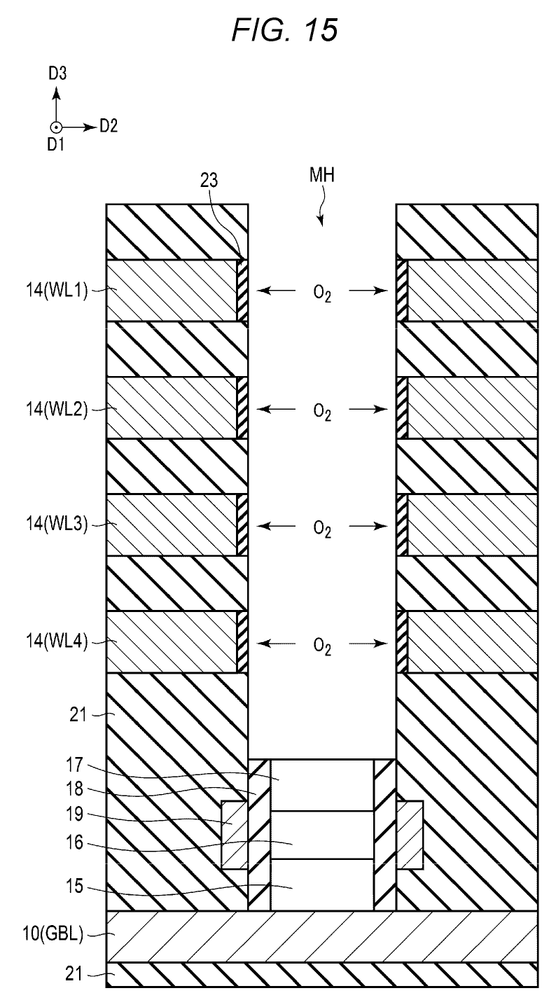

Next, a method for manufacturing a memory cell array is described with reference to FIG. 14 and FIG. 15. In the second embodiment, unlike the first embodiment, the method may form the WL wiring layers 14 without performing back-filling. Furthermore, in the following description, a method for forming the memory string 13 and the WL wiring layers 14 is described.

As illustrated in FIG. 14, in the first example, after stacking four WL wiring layers 14 in layers without using the sacrificial layer 30, the method may form the memory hole MH.

As illustrated in FIG. 15, next, the method may form the oxide layer 23 by performing oxidation treatment on the surface of the WL wiring layer 14 exposed on the side surface of the memory hole MH. In the subsequent processes, the method may perform embedding in the memory hole MH to form the memory string 13 in a procedure similar to that illustrated in FIG. 8 of the first embodiment. Furthermore, in this instance, the surface of the drain region 17 of the select transistor ST1 may be also oxidized, but such an oxidized area can be removed by wet etching using a hydrofluoric acid based chemical. Alternatively, an oxidized area of the surface of the drain region 17 can be removed by anisotropy etching.

### 2.2 Second Example

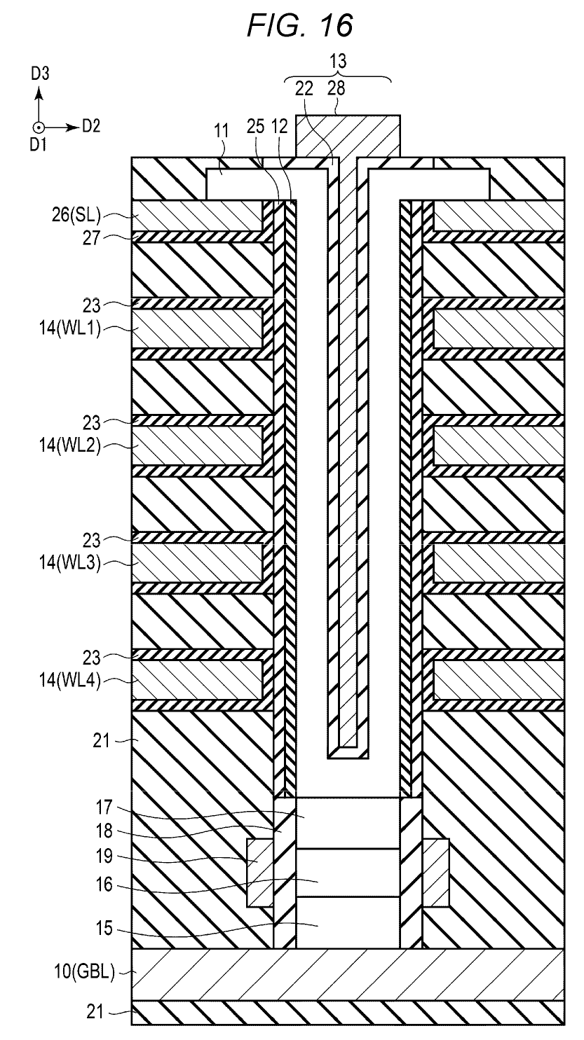

Next, a structure of the memory cell array 2 according to a second example is described with reference to FIG. 16. FIG. 16 illustrates a sectional view of the memory cell array 2.

As illustrated in FIG. 16, in the second example, SL wiring layer 26, which serves as a source line SL, and an oxide layer 27, which covers the bottom surface and a part of the side surfaces of the SL wiring layer 26, may be provided above the WL wiring layer 14 which serves as the word line WL1, via the insulating layer 21, Then, a part of the upper surface of the SL wiring layer 26 serving as the source line SL may be electrically connected to the semiconductor layer 11, Furthermore, the oxide layer 27 can be omitted, and, instead of the oxide layer 27, a conductive barrier metal for preventing or reducing a reaction between the SL wiring layer 26 and the insulating layer 21 can be used. The SL wiring layer 26 may be configured with an electrical conducting material, and can be made from the same material as, for example, that of the WL wiring layer 14. The oxide layer 27 can be made from the same material as, for example, that of the oxide layer 23 or the oxide layer 25.

Moreover, in the memory string 13, an electrode 28 and an insulating layer 22, which covers the side surface and bottom surface of the electrode 28, may be embedded in the inside of the semiconductor layer 11. In the second example, the electrode 28 may form channels in the vicinity of an interface with the insulating layer 22 in the semiconductor layer 11, and may serve as a gate line GL forming a path (or channel) for allowing a current to flow from, for example, the global bit line GBL to the source line SL.

Therefore, the electrode 28 in the second example may be connected to a wiring layer (not illustrated) serving as a gate line GL, and, for example, a voltage may be applied thereto from, for example, the sense amplifier 4.

### 2.3 Advantageous Effect According to Second Embodiment

With a configuration according to the second embodiment, employed, an advantageous effect similar to that of the first embodiment can be attained.

Moreover, with a configuration according to the first example of the second embodiment employed, any deterioration of film quality of the oxide layer 23 having a levelling-off structure can be prevented or reduced. Such an advantageous effect is described in detail.

For example, a method of, after boring the memory hole MH, causing the WL wiring layer 14 exposed on the side surface of the memory hole MH to recede by, for example, wet etching, and embedding, for example, TiOₓ in the receding portion, thus forming the oxide layer 23, can be performed. In such a method, TiOₓ is formed with a film thickness larger than the film thickness of the receding WL wiring layer 14, and surplus TiOₓ is removed by anisotropy etching. In this instance, processing damage may occur on the surface of TiOₓ of the receding portion, so that defect levels may be formed in the damaged layer. When fixed charge is formed in the oxide layer 23 by defect levels, the mobility of channels lowers and a cell current in the longitudinal direction (or the third direction D3) decreases. Since, when the cell current decreases, the time of current sensing in a sense amplifier becomes slow, the action velocity of a device decreases. Furthermore, variations in the thickness of a damage layer of the oxide layer 23 occur between the memory cell transistors MT depending on, for example, differences of height positions in the memory hole MH. Therefore, the necessity of additionally setting a design margin in such a way as to make characteristics uniform between the memory cell transistors MT arises.

Moreover, when, for example, TiOₓ is embedded in a receding portion of the WL wiring layer 14, voids or seams may be formed in the receding portion. These also become lattice defects in the oxide layer 23 and may affect characteristics of a device.

On the other hand, in a configuration according to the first example of the second embodiment, when the oxide layer 23 having a levelling-off structure is formed, the oxide layer 23 can be formed by oxidizing the surface of the WL wiring layer 14 exposed on the memory hole MH. Accordingly, since the surface of the oxide layer 23 is not exposed to an etching atmosphere, it is possible that there is no deterioration of film quality caused by etching damage, and variations in characteristic of the memory cell transistor MT can be reduced. Accordingly, the reliability of a nonvolatile semiconductor memory device can be improved.

### 3. Modification Examples and Others

In some embodiments, a nonvolatile semiconductor memory device may include a semiconductor substrate, a first wiring layer (e.g., GBL wiring layers 10 in FIG. 2) provided above the semiconductor substrate and extending in a second direction (e.g., the direction D2 in FIG. 2), a plurality of second wiring layers (WL wiring layers 14 in FIG. 2) provided above the first wiring layer, extending in a first direction (e.g., the direction D1 in FIG. 2) intersecting with the first direction, and arrayed along a third direction (e.g., the direction D3 in FIG. 2) intersecting with the first direction and the second direction and perpendicular to the semiconductor substrate, a semiconductor layer (e.g., the semiconductor layer 11 in FIG. 2) extending along the third direction and electrically connected to the first wiring layer, a first insulating layer (e.g., insulating layer 12 in FIG. 2) extending along the third direction, being in contact with the semiconductor layer, and provided between the semiconductor layer and the plurality of second wiring layers, a first oxide layer (the oxide layer 25 in FIG. 3) extending along the third direction, being in contact with the first insulating layer, and provided between the first insulating layer and the plurality of second wiring layers, and a plurality of second oxide layers (the oxide layer 23 in FIG. 3) having first sides being respectively in contact with the plurality of second wiring layers and having second sides being in contact with the first oxide layer, a resistance value of a stacked film configured with the first oxide layer and the plurality of second oxide layers varying according to a voltage being applied to the plurality of second wiring layers.

With the above-described embodiments employed, a nonvolatile semiconductor memory device capable of preventing or reducing an increase in chip area can be provided.

For example, while, in the description of the above-described embodiments, the memory string 13 is formed on the select transistor ST1, the memory string 13 may include the select transistors ST1 and ST2.

Moreover, the above-described embodiments are directed to a three-dimensional stacked-type memory in which a plurality of memory cell transistors MT is stacked in layers above a semiconductor substrata, but can be applied to a plane type memory in which a plurality of memory cell transistors MT is two-dimensionally arranged on a semiconductor substrate.

Furthermore, the term “connection” in the above-described embodiments includes a state of being indirectly interconnected with any other thing, such as a transistor or a resistor, lying between two things.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit, of the present disclosure. The accompanying claims and their equivalents are intended to cover such forms or modifications as would fall within the scope and spirit of the present disclosure.

What is claimed is:

1. A nonvolatile semiconductor memory device comprising:
a semiconductor substrate;
a first wiring layer provided above the semiconductor substrate;
a plurality of second wiring layers provided above the first wiring layer, extending in a first direction intersecting with a second direction in which the first wiring layer extends, and arrayed along a third direction intersecting with the first direction and the second direction and perpendicular to the semiconductor substrate;
a semiconductor layer extending along the third direction and electrically connected to the first wiring layer;
a first insulating layer extending along the third direction, being in contact with the semiconductor layer, and provided between the semiconductor layer and the plurality of second wiring layers;
a first oxide layer extending along the third direction, being in contact with the first insulating layer, and provided between the first insulating layer and the plurality of second wiring layers; and
a plurality of second oxide layers having first sides being respectively in contact with the plurality of second wiring layers and having second sides being in contact with the first oxide layer, a resistance value of a stacked film configured with the first oxide layer and the plurality of second oxide layers varying according to a voltage being applied to the plurality of second wiring layers.

2. The nonvolatile semiconductor memory device according to claim 1, wherein each of the first oxide layer and the plurality of second oxide layers includes at least one of titanium, tungsten, niobium, or molybdenum.

3. The nonvolatile semiconductor memory device according to claim 1, wherein the stacked film configured with the first oxide layer and the plurality of second oxide layers is in a crystallized state.

4. The nonvolatile semiconductor memory device according to claim 1, wherein a respective one of the plurality of second oxide layers is in contact with an upper surface, a bottom surface, and a part of side surfaces of a corresponding one of the plurality of second wiring layers.

5. The nonvolatile semiconductor memory device according to claim 4, wherein a film thickness in the second direction of the stacked film configured with the first oxide layer and the plurality of second oxide layers is larger than a film thickness in the third direction of each of the plurality of second oxide layers being in contact with the upper surface of a corresponding one of the plurality of second wiring layers.

6. The nonvolatile semiconductor memory device according to claim 3, wherein, in the stacked film in a crystallized state, grains of the first oxide layer and grains of the plurality of second oxide layers are divided from each other at an interface between the first oxide layer and the plurality of second oxide layers.

7. The nonvolatile semiconductor memory device according to claim 2, wherein the plurality of second wiring layers and the plurality of second oxide layers include an identical metal material.

8. The nonvolatile semiconductor memory device according to claim 1, wherein the first insulating layer includes at least one of aluminum, hafnium, zirconium, tantalum, silicon, or germanium.

9. The nonvolatile semiconductor memory device according to claim 1, further comprising:
a plurality of third wiring layers adjacent to the plurality of second wiring layers in the second direction via the semiconductor layer and arranged along the third direction;
a second insulating layer being in contact with the semiconductor layer and provided between the semiconductor layer and the plurality of third wiring layers;
a third oxide layer being in contact with the second insulating layer and provided between the second insulating layer and the plurality of third wiring layers; and
a plurality of fourth oxide layers having first sides being respectively in contact with the plurality of third wiring layers and having second sides being in contact with the third oxide layer, a resistance value of a stacked film configured with the third oxide layer and the plurality of fourth oxide layers varying according to a voltage being applied to the plurality of third wiring layers.

10. The nonvolatile semiconductor memory device according to claim 1, wherein a respective one of the plurality second wiring layers is free of the second oxide layers or an upper surface and a bottom surface of the respective second wiring layer.

11. A method for manufacturing nonvolatile semiconductor memory device, the method comprising:
forming a first wiring layer above a semiconductor substrate;
stacking, above the first wiring layer, a plurality of sacrificial layers with respective ones of plurality of insulating layers interposed therebetween, the plurality of sacrificial layers being stacked in a third direction intersecting with a first direction in which the plurality of sacrificial layers extends and a second direction in which the first wiring layer extends;
forming a memory hole penetrating the stacked plurality of sacrificial layers such that a bottom surface of the memory hole reaches above the first wiring layer;
forming a semiconductor layer in the memory hole to extend along the third direction and be electrically connected to the first wiring layer;
forming a first insulating layer in the memory hole between the semiconductor layer and the plurality of sacrificial layers to extend along the third direction and be in contact with the semiconductor layer;
forming a first oxide layer in the memory hole between the first insulating layer and the plurality of sacrificial layers to extend along the third direction and be in contact with the first insulating layer;
etching the plurality of sacrificial layers to form a plurality of gaps; and
forming a plurality of second wiring layers and a plurality of second oxide layers in the plurality of gaps such that the plurality of second oxide layers have first, sides thereof being respectively in contact with the plurality of second wiring layers and have second sides thereof being in contact with the first oxide layer.

12. The method according to claim 11, wherein a respective one of the plurality of second oxide layers is in contact with an upper surface, a bottom surface, and a part of side surfaces of a corresponding one of the plurality of second wiring layers.

13. The method according to claim 12, wherein a film thickness in the second direction of a stacked film configured with the first oxide layer and the plurality of second oxide layers is larger than a film thickness in the third direction of each of the plurality of second oxide layers being in contact with the upper surface of a corresponding one of the plurality of second wiring layers.

14. A method for manufacturing a nonvolatile semiconductor memory device, the method comprising:
forming a first wiring layer above a semiconductor substrate;
stacking, above the first wiring layer, a plurality of second wiring layers with respective ones of a plurality of insulating layers interposed therebetween, the plurality of second wiring layers being stacked in a third direction intersecting with a first direction in which the plurality of second wiring layers extends and a second direction in which the first wiring layer extends;
forming a memory hole penetrating the stacked plurality of second wiring layers such that a bottom surface of the memory hole reaches above the first wiring layer;
forming a semiconductor layer in the memory hole to extend along the third direction and be electrically connected to the first wiring layer;
forming a first insulating layer in the memory hole between the semiconductor layer and the plurality of second wiring layers to extend along the third direction and be in contact with the semiconductor layer;
forming a first oxide layer in the memory hole between the first insulating layer and the plurality of second wiring layers to extend along the third direction and be in contact with the first insulating layer; and
forming, after forming the memory hole and before forming the semiconductor layer, a plurality of second oxide layers on a surface of the plurality of second wiring layers exposed on a side surface of the memory hole.

15. The method according to claim 14, wherein the plurality of second oxide layers are formed by performing oxidation treatment on the surface of the plurality of second wiring layers exposed on the side surface of the memory hole.
